(19) United States
(12) Patent Application Publication
(10) Pub. No.: US 2024/0122045 A1
(43) Pub. Date: Apr. 11, 2024

(54) DISPLAY DEVICE

(71) Applicant: Samsung Display Co., Ltd., Yongin-si (KR)

(72) Inventors: GAK SEOK LEE, Yongin-si (KR); KEUNCHAN OH, Yongin-si (KR); MIN-JAE KIM, Yongin-si (KR); KYUNGHAE PARK, Yongin-si (KR); JAE CHEOL PARK, Yongin-si (KR); INSEOK SONG, Yongin-si (KR); JISEONG YANG, Yongin-si (KR)

(21) Appl. No.: 18/237,770

(22) Filed: Aug. 24, 2023

(30) Foreign Application Priority Data
Oct. 11, 2022 (KR) 10-2022-0129410

(51) Int. Cl. H10K 59/80; H10K 59/38

(52) U.S. Cl. CPC H10K 59/8791; H10K 59/38; H10K 59/352

(57) ABSTRACT

A display device includes: a display panel including a first light emitting area to emit a source light; a barrier wall on the display panel, and having a first opening corresponding to the first light emitting area; a first light control pattern in the first opening; and a light shielding pattern between the display panel and the barrier wall, and overlapping with the barrier wall and the first opening. The light shielding pattern overlaps with a portion of the first light control pattern.

### CROSS-REFERENCE TO RELATED APPLICATION

This application claims priority to and the benefit of Korean Patent Application No. 10-2022-0129410, filed on Oct. 11, 2022, the entire content of which is incorporated by reference herein.

### BACKGROUND

### 1. Field

Aspects of embodiments of the present disclosure relate to a display device. More particularly, aspects of embodiments of the present disclosure relate to a display device including a light conversion pattern.

### 2. Description of the Related Art

Display devices are classified into a transmissive display device that selectively transmits a source light generated by a light source, and an emissive display device that generates the source light. The display device includes different kinds of functional patterns depending on the pixels to generate images. The functional patterns may transmit a partial wavelength range of the source light, or may convert a color of the source light.

The above information disclosed in this Background section is for enhancement of understanding of the background of the present disclosure, and therefore, it may contain information that does not constitute prior art.

### SUMMARY

One or more embodiments of present disclosure are directed to a display device having a reduced defect rate.

According to one or more embodiments of the present disclosure, a display device includes: a display panel including a first light emitting area configured to emit a source light; a barrier wall on the display panel, and having a first opening corresponding to the first light emitting area; a first light control pattern in the first opening; and a light shielding pattern between the display panel and the barrier wall, and overlapping with the barrier wall and the first opening. The light shielding pattern overlaps with a portion of the first light control pattern.

In an embodiment, the first light emitting area may be located in the first opening in a plan view, and the first light emitting area may be biased to one side of the first opening in a first direction.

In an embodiment, the light shielding pattern may have a first-first opening corresponding to the first opening, and the first-first opening may have a size smaller than a size of the first opening in a plan view.

In an embodiment, the light shielding pattern may entirely overlap with the barrier wall in a plan view.

In an embodiment, the display device may further include a first color filter on the barrier wall. The first light control pattern may be configured to convert the source light to a first output light having a color different from a color of the source light, and the first color filter may be configured to block the source light and transmit the first output light.

In an embodiment, the first light control pattern comprises a base resin, and a quantum dot dispersed in the base resin.

In an embodiment, the display device may further include a second color filter and a third color filter overlapping with the first color filter. The first color filter may include a first pixel area that does not overlap with the second color filter and the third color filter, and the first pixel area may overlap with the first light emitting area in a plan view.

In an embodiment, the light shielding pattern may have a first-first opening corresponding to the first opening, the first-first opening may be smaller than the first opening in a plan view, and the first pixel area may have a width equal to or greater than a width of the first-first opening in a first direction.

In an embodiment, the display device may further include a second light control pattern. The display panel may further include a second light emitting area configured to emit the source light. The barrier wall may have a second opening corresponding to the second light emitting area, and the second light control pattern may be in the second opening.

In an embodiment, the light shielding pattern may further overlap with the second opening.

In an embodiment, the first opening and the second opening may be spaced from each other in a first direction; a first portion of the light shielding pattern may overlap with an area between the first opening and the second opening in the first direction; a second portion of the light shielding pattern may extend from the first portion of the light shielding pattern, and may overlap with the first opening; and a third portion of the light shielding pattern may extend from the first portion of the light shielding pattern, and may overlap with the second opening.

In an embodiment, a shortest distance in a first direction between the first opening and the second opening may be within a range from about 5 micrometers to about 8 micrometers.

In an embodiment, a first portion of the light shielding pattern may overlap with an area between the first opening and the second opening; a second portion of the light shielding pattern may extend from the first portion of the light shielding pattern, and may overlap with the first opening; and a sum of a width of the first portion and a width of the second portion of the light shielding pattern in the first direction may be greater than the shortest distance.

In an embodiment, the first opening may have a width equal to or greater than about 41 micrometers in the first direction.

In an embodiment, the display device may further include a base layer facing the display panel in a thickness direction of the display panel, and the barrier wall may be on a lower surface of the base layer.

In an embodiment, the barrier wall may further have a dummy opening defining a main well area that does not overlap with the first light emitting area in a plan view, and a sub-opening defining a sub-well area between the first light emitting area and the main well area, and the light shielding pattern may overlap with the main well area or the sub-well area.

According to one or more embodiments of the present disclosure, a display device includes: a display panel including a light emitting element; and a light conversion panel spaced from the display panel in a thickness direction of the display panel, the light conversion panel including: a base layer; a barrier wall on a lower surface of the base layer, and having an opening corresponding to the light emitting element; a light control pattern in the opening; and a light shielding pattern under the barrier wall, and overlapping with the barrier wall and the opening. The light shielding pattern overlaps with a portion of the light control pattern.

In an embodiment, the light emitting element may be in the opening in a plan view, and the light emitting element may be biased to one side of the opening in a first direction.

According to one or more embodiments of the present disclosure, a display device includes: a light emitting element; a thin film encapsulation layer encapsulating the light emitting element; a barrier wall on the thin film encapsulation layer, and having an opening corresponding to the light emitting element; a light control pattern in the opening; and a light shielding pattern between the barrier wall and the thin film encapsulation layer, and overlapping with the barrier wall and the opening. The light shielding pattern overlaps with a portion of the light control pattern.

In an embodiment, the light emitting element may be in the opening in a plan view, and the light emitting element may be biased to one side of the opening in a first direction.

According to one or more embodiments of the present disclosure, a size of an opening of a barrier wall may be increased, and thus, defects caused by a mixture of light control materials in an inkjet process may be prevented or substantially prevented. Accordingly, color purity of output light provided from a pixel area may be improved.

According to one or more embodiments of the present disclosure, leak light (e.g., leakage light) from an adjacent light emitting area may be shielded by a light shielding pattern. Accordingly, display quality of the images may be improved.

### BRIEF DESCRIPTION OF THE DRAWINGS

The above and other aspects and features of the present disclosure will be more clearly understood from the following detailed description of the illustrative, non-limiting embodiments with reference to the accompanying drawings, in which:

FIG. 1A is a perspective view of a display device according to an embodiment of the present disclosure;

FIG. 1B is a cross-sectional view of a display device according to an embodiment of the present disclosure;

FIG. 1C is a plan view of a display panel according to an embodiment of the present disclosure;

FIG. 2 is an equivalent circuit diagram of a pixel according to an embodiment of the present disclosure;

FIG. 3A is an enlarged plan view of a display area according to an embodiment of the present disclosure;

FIG. 3B is a cross-sectional view of a display device taken along the line I-I′ of FIG. 3A;

FIG. 4A is a plan view of a barrier wall and a light control pattern according to an embodiment of the present disclosure;

FIG. 4B is a plan view of a light shielding pattern according to an embodiment of the present disclosure;

FIGS. 5A and 5B are plan views of a light shielding pattern according to one or more embodiments of the present disclosure;

FIG. 6A is a plan view of a barrier wall and a light control pattern according to an embodiment of the present disclosure;

FIG. 6B is a plan view of a light shielding pattern according to an embodiment of the present disclosure;

FIG. 6C is a cross-sectional view of a light conversion panel taken along the line II-II′ of FIG. 6B;

FIG. 7A is an enlarged plan view of a display area according to an embodiment of the present disclosure;

FIG. 7B is a cross-sectional view of a display device taken along the line I-I′ of FIG. 7A;

FIG. 8A is a perspective view of a display device according to an embodiment of the present disclosure; and

FIG. 8B is a cross-sectional view of a display device according to an embodiment of the present disclosure.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

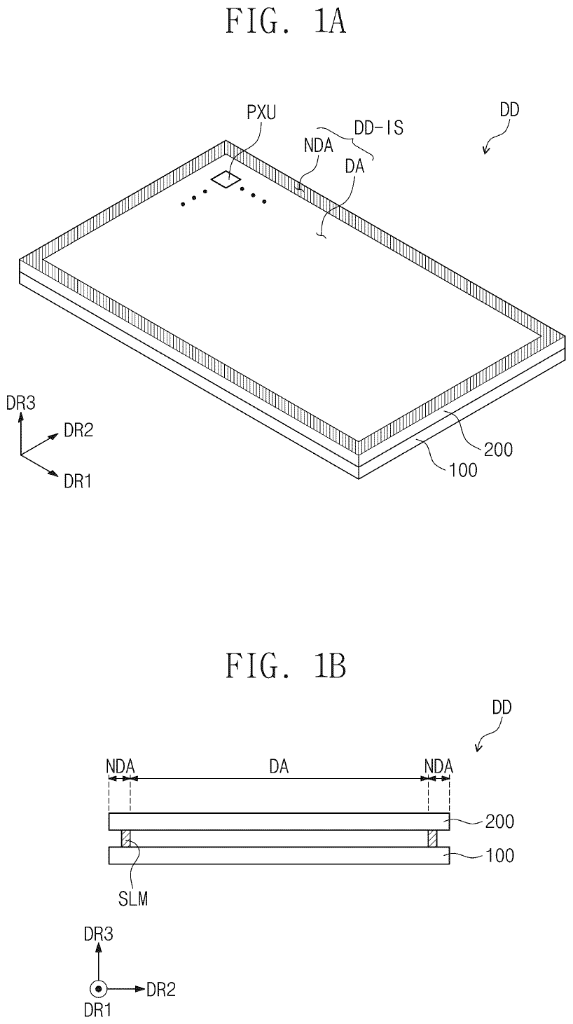

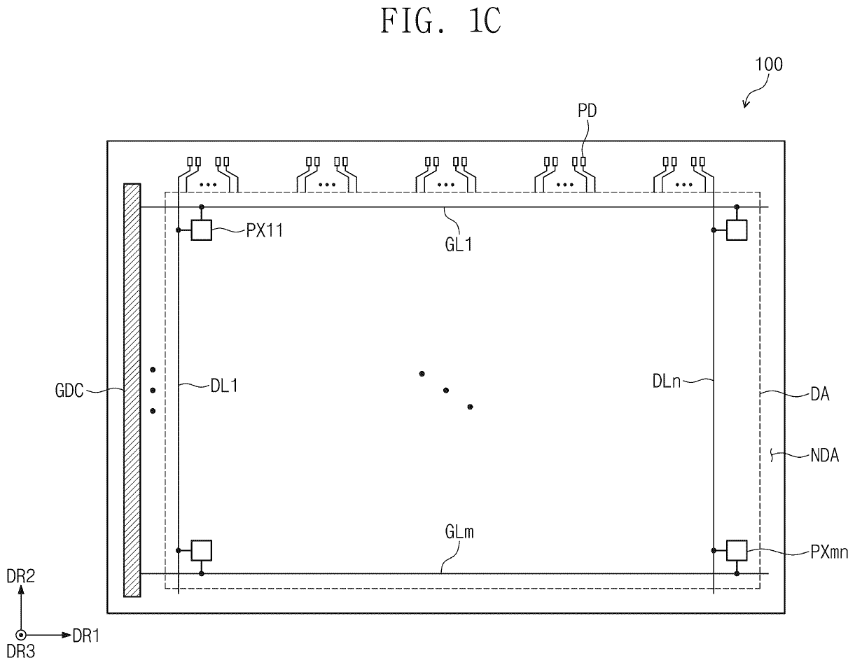

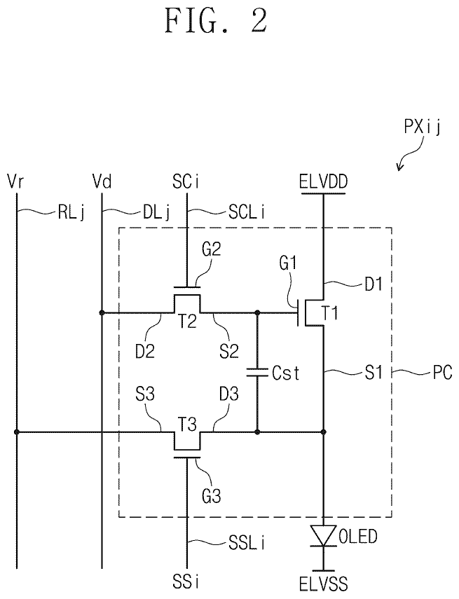

FIG. 1A is a perspective view of a display device DD according to an embodiment of the present disclosure. FIG. 1B is a cross-sectional view of the display device DD according to an embodiment of the present disclosure. FIG. 1C is a plan view of a display panel 100 according to an embodiment of the present disclosure.

Referring to FIG. 1A, the display device DD may display an image through a display surface DD-IS. The display surface DD-IS may be parallel to or substantially parallel to a plane defined by a first direction DR1 and a second direction DR2. An upper surface of a member disposed at an uppermost position (e.g., in a third direction DR3) of the display device DD may be defined as the display surface DD-IS.

The third direction DR3 may indicate a normal line direction of the display surface DD-IS (e.g., a thickness direction of the display device DD). Front (or upper) and rear (or lower) surfaces of each layer or each unit may be distinguished from each other in the third direction DR3.

The display device DD may include a display area DA and a non-display area NDA. Unit pixels PXU may be arranged in the display area DA, and the unit pixels PXU may not be arranged in the non-display area NDA. The non-display area NDA may be defined along an edge of the display surface DD-IS. The non-display area NDA may surround (e.g., around a periphery of) the display area DA. According to an embodiment, the non-display area NDA may be omitted as needed or desired, or may be defined to be adjacent to one side (e.g., only one side) of the display area DA. FIG. 1A shows a flat or substantially flat display device DD as a representative example, but the present disclosure is not limited thereto, and the display device DD may have a curved shape, may be rollable, or may be slidable from a housing.

The unit pixels PXU shown in FIG. 1A may define a pixel row and a pixel column. The unit pixel PXU may be the smallest repeating unit capable of providing one or more colors of light, and may include at least one pixel. The unit pixel PXU may include a plurality of pixels that provide light of different colors from each other.

Referring to FIG. 1B, the display device DD may include the display panel 100 (e.g., a lower display substrate), and a light conversion panel 200 (e.g., an upper display substrate) facing the display panel 100 and spaced apart from the display panel 100. A cell gap (e.g., a predetermined cell gap) may be defined between the display panel 100 and the light conversion panel 200. The cell gap may be maintained by a sealing member SLM connecting (e.g., attaching or coupling) the display panel 100 and the light conversion panel 200 to each other. The sealing member SLM may include a binder resin, and inorganic fillers mixed with the binder resin. The sealing member SLM may further include other suitable additives. The additives may include an amine-based curing agent and a photoinitiator. The additives may further include a silane-based additive and an acrylic-based additive. The sealing member SLM may include an inorganic-based material, such as a frit.

Still referring to FIG. 1B, each of the display panel 100 and the light conversion panel 200 may include a display area DA and a non-display area NDA defined therein, which may be the same or substantially the same as the display area DA and the non-display area NDA, respectively, of the display device DD. Hereinafter, the display area DA of the display device DD may indicate the display area DA of each of the display panel 100 and the light conversion panel 200, and the non-display area NDA of the display device DD may indicate the non-display area NDA of each of the display panel 100 and the light conversion panel 200.

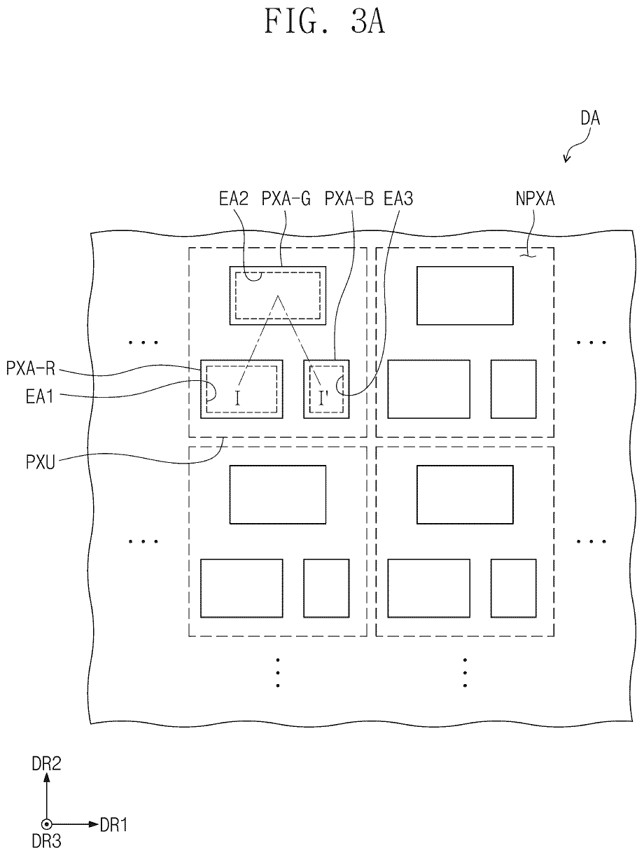

FIG. 1C shows an arrangement relationship of signal lines GL1 to GLm and DL1 to DLn and pixels PX11 to PXnm in a plan view, where n and m are natural numbers of two or more. The signal lines GL1 to GLm and DL1 to DLn may include a plurality of gate lines GL1 to GLm and a plurality of data lines DL1 to DLn. The plurality of gate lines GL1 to GLm shown in FIG. 1C are representative of the signal lines for providing scan signals. In other words, the plurality of gate lines GL1 to GLm may include a first group of signal lines and a second group of signal lines. The first group of signal lines may include an i-th scan line (e.g., see SCLi in FIG. 2), and the second group of signal lines may include an i-th sensing line (e.g., see SSLi in FIG. 2), which will be described in more detail below.

Each of the pixels PX11 to PXnm may be connected to a corresponding gate line from among the gate lines GL1 to GLm and a corresponding data line from among the data lines DL1 to DLn. Each of the pixels PX11 to PXnm may include a pixel driving circuit and a light emitting element. More kinds of signal lines may be provided in the display panel 100 according to a configuration of the pixel driving circuit of each of the pixels PX11 to PXnm.

A gate driving circuit GDC may be integrated in the display panel 100 through an oxide silicon gate driver circuit (OSG) process or an amorphous silicon gate driver circuit (ASG) process. The gate driving circuit GDC is connected to the gate lines GL1 to GLm, and may be disposed at (e.g., in or on) one side of the non-display area NDA in the first direction DR1. Pads PD connected to ends of the data lines DL1 to DLn may be disposed at (e.g., in or on) one side of the non-display area NDA in the second direction DR2.

FIG. 2 is an equivalent circuit diagram of a pixel PXij according to an embodiment of the present disclosure.

FIG. 2 shows the pixel PXij connected to the i-th scan line SCLi, the i-th sensing line SSLi, a j-th data line DLj, and a j-th reference line RLj as a representative example. Here, i may be a natural number from among 1 to m, and j may be a natural number from among 1 to n. The pixel PXij may include a pixel driving circuit PC, and a light emitting element OLED electrically connected to the pixel driving circuit PC. The pixel driving circuit PC may include a plurality of transistors T1 to T3, and a capacitor Cst. The transistors T1 to T3 may be formed through a low temperature polycrystalline silicon (LTPS) process or a low temperature polycrystalline oxide (LTPO) process. Hereinafter, for convenience, the transistors T1 to T3 will be described in more detail in the context of an N-type transistor, but the present disclosure is not necessarily limited thereto or thereby. According to an embodiment, at least one of the transistors T1 to T3 may be a P-type transistor.

In the present embodiment, the pixel driving circuit PC may include a first transistor T1 (e.g., a driving transistor), a second transistor T2 (e.g., a switching transistor), a third transistor T3 (e.g., a sensing transistor), and the capacitor Cst. However, the pixel driving circuit PC should not be necessarily limited thereto or thereby. According to an embodiment, the pixel driving circuit PC may further include one or more additional transistors and/or one or more additional capacitors.

The light emitting element OLED may be an organic light emitting element, which includes an anode (e.g., a first electrode) and a cathode (e.g., a second electrode), or an inorganic light emitting element. The anode of the light emitting element OLED may receive a first voltage ELVDD via the first transistor T1, and the cathode of the light emitting element OLED may receive a second voltage ELVSS. The light emitting element OLED may emit light in response to the first voltage ELVDD and the second voltage ELVSS.

The first transistor T1 may include a drain D1 for receiving the first voltage ELVDD, a source S1 connected to the anode of the light emitting element OLED, and a gate G1 connected to the capacitor Cst. The first transistor T1 may control a driving current flowing from the first voltage ELVDD to the light emitting element OLED in response to a level of a voltage charged in the capacitor Cst.

The second transistor T2 may include a drain D2 connected to the j-th data line DLj, a source S2 connected to the capacitor Cst, and a gate G2 for receiving an i-th first scan signal SCi. The j-th data line DLj may receive a data voltage Vd. The second transistor T2 may apply the data voltage Vd to the first transistor T1 in response to the i-th first scan signal SCi.

The third transistor T3 may include a source S3 connected to the j-th reference line RLj, a drain D3 connected to the anode of the light emitting element OLED, and a gate G3 for receiving an i-th second scan signal SSi. The j-th reference line RLj may receive a reference voltage Vr. The third transistor T3 may initialize the capacitor Cst and the anode of the light emitting element OLED.

The capacitor Cst may be charged with electric charges corresponding to a difference between the voltage from the second transistor T2 and the first voltage ELVDD. The capacitor Cst may be connected to the gate G1 of the first transistor T1 and the anode of the light emitting element OLED.

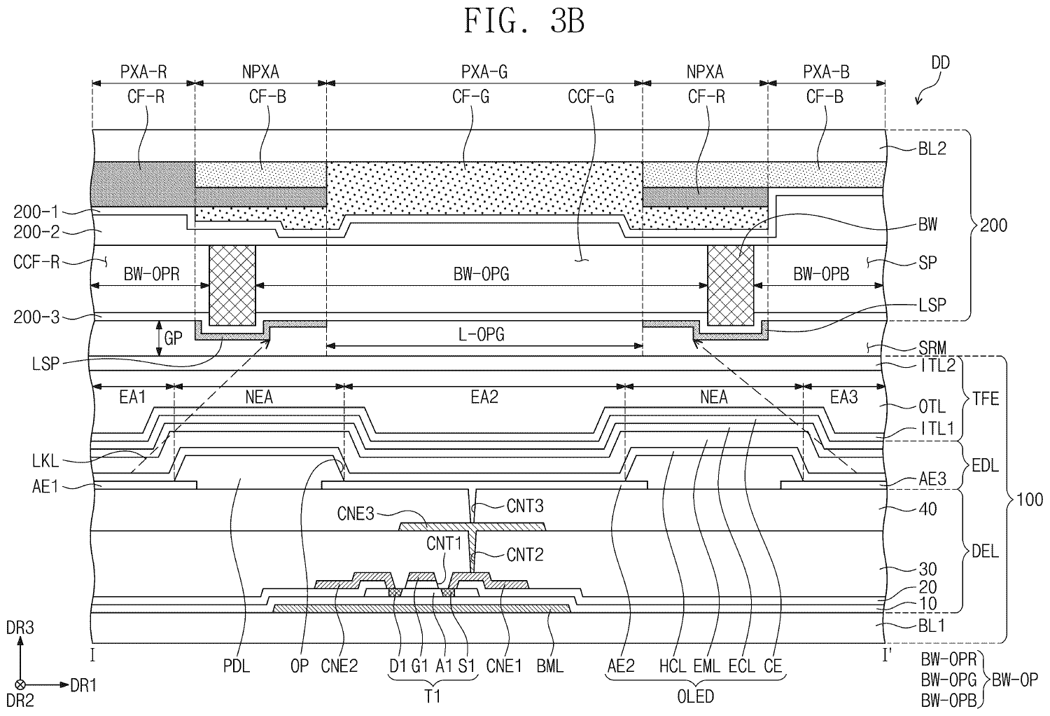

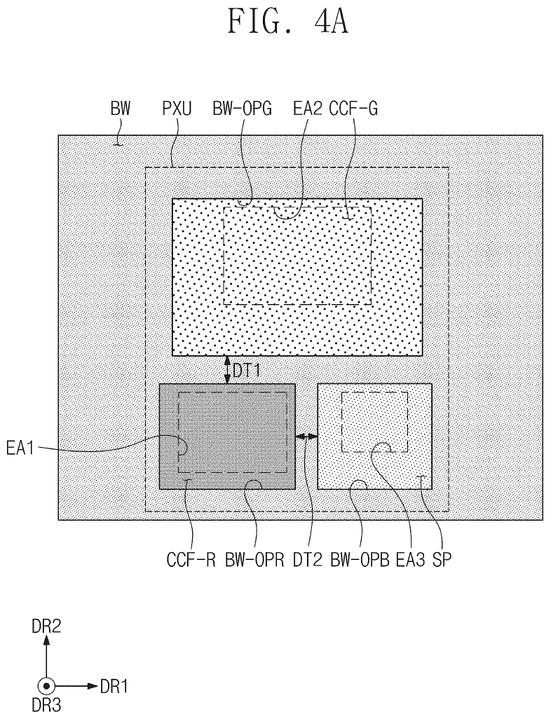

FIG. 3A is an enlarged plan view of the display area DA according to an embodiment of the present disclosure. FIG. 3B is a cross-sectional view of the display device DD taken along the line I-I′ of FIG. 3A.

Referring to FIG. 3A, the unit pixels PXU may be arranged along the first direction DR1 and the second direction DR2. In the present embodiment, the unit pixel PXU may include a first pixel, a second pixel, and a third pixel, which emit light having different colors from each other. The first pixel, the second pixel, and the third pixel may emit red light, green light, and blue light, respectively. FIG. 3A shows a first light emitting area EA1, a second light emitting area EA2, and a third light emitting area EA3 as representative examples of the first pixel, the second pixel, and the third pixel, respectively. In addition, a first pixel area PXA-R, a second pixel area PXA-G, and a third pixel area PXA-B, which correspond to the first light emitting area EA1, the second light emitting area EA2, and the third light emitting area EA3, respectively, are shown.

Each of the first light emitting area EA1, the second light emitting area EA2, and the third light emitting area EA3 may be aligned with a corresponding pixel area from among the first pixel area PXA-R, the second pixel area PXA-G, and the third pixel area PXA-B. The expression “the light emitting area is aligned with the pixel area” may mean that a center of the light emitting area may coincide with a center of the pixel area. In addition, the expression “the light emitting area is aligned with the pixel area” may mean that distances between an edge of the light emitting area and an edge of the pixel area at both sides in the first direction DR1 are the same or substantially the same as each other, and distances between an edge of the light emitting area and an edge of the pixel area at both sides in the second direction DR2 are the same or substantially the same as each other.

The first light emitting area EA1 may be an area where a source light of the first pixel is generated. The second light emitting area EA2 may be an area where a source light of the second pixel is generated. The third light emitting area EA3 may be an area where a source light of the third pixel is generated. The first pixel area PXA-R may be an area where an output light of the first pixel is provided to the outside. The second pixel area PXA-G may be an area where an output light of the second pixel is provided to the outside. The third pixel area PXA-B may be an area where an output light of the third pixel is provided to the outside.

A peripheral area NPXA may be defined between the first, second, and third pixel areas PXA-R, PXA-G, and PXA-B. The peripheral area NPXA may define a boundary of the first, second, and third pixel areas PXA-R, PXA-G, and PXA-B, and may prevent or substantially prevent color mixture between the first, second, and third pixel areas PXA-R, PXA-G, and PXA-B.

Still referring to FIG. 3A, the first pixel area PXA-R and the third pixel area PXA-B may be arranged in the same row as each other, and the second pixel area PXA-G may be arranged in a row different from the row in which the first pixel area PXA-R and the third pixel area PXA-B are arranged. The second pixel area PXA-G may have the largest size, and the third pixel area PXA-B may have the smallest size, but the present disclosure is not limited thereto or thereby. In the present embodiment, each of the first pixel area PXA-R, the second pixel area PXA-G, and the third pixel area PXA-B has a quadrangular or substantially quadrangular shape, but the present disclosure is not limited thereto.

FIG. 3B mainly shows the second pixel area PXA-G, and illustrates a cross-section of the first transistor T1 as a representative example. The first pixel area PXA-R and the third pixel area PXA-B may have the same or substantially the same stacked structure as that of the second pixel area PXA-G illustrated in FIG. 3B.

The display panel 100 may include a first base layer BL1, a driving element layer DEL, a light emitting element layer EDL, and a thin film encapsulation layer TFE. The driving element layer DEL may be disposed on the first base layer BL1. The driving element layer DEL may include a plurality of insulating layers, a plurality of conductive layers, and a semiconductor layer. The light emitting element layer EDL may be disposed on the driving element layer DEL. The thin film encapsulation layer TFE may be disposed on the light emitting element layer EDL, and may encapsulate the light emitting element layer EDL.

The first base layer BL1 may include glass or a synthetic resin layer. The synthetic resin layer may include a heat curable resin. The synthetic resin layer may be a polyimide-based resin layer, but the present disclosure is not limited thereto or thereby. The synthetic resin layer may include at least one of an acrylic-based resin, a methacrylic-based resin, a polyisoprene-based resin, a vinyl-based resin, an epoxy-based resin, a urethane-based resin, a cellulose-based resin, a siloxane-based resin, a polyimide-based resin, or a perylene-based resin. The base layer may include a glass substrate, a metal substrate, or an organic/inorganic composite material substrate.

A metal pattern BML may be disposed on the first base layer BL1. A signal line may be disposed at (e.g., in or on) the same layer as that of the metal pattern BML. A first insulating layer 10 may be disposed on the first base layer BL1 to cover the metal pattern BML.

A semiconductor pattern may be disposed on the first insulating layer 10, and may overlap with the metal pattern BML. The semiconductor pattern may have different electrical properties depending on whether or not it is doped, and/or whether it is doped with an N-type dopant or a P-type dopant. The semiconductor pattern may include a first region having a relatively high conductivity and a second region having a relatively low conductivity. The first region may be doped with the N-type dopant or the P-type dopant. A P-type transistor may include a doped region doped with the P-type dopant, and an N-type transistor may include a doped region doped with the N-type dopant. The second region may be a non-doped region or a region that is doped at a concentration lower than that of the first region.

The semiconductor pattern may include a source area S1, a channel area A1 (e.g., an active area), and a drain area D1. The same reference numerals as those of the source area S1 and drain area D1 described above with reference to FIG. 2 may refer to the source S1 and the drain D1 illustrated in FIG. 3B. A second insulating layer 20 may be disposed on the first insulating layer 10. Contact holes CNT1 may be defined through (e.g., may penetrate) the second insulating layer 20 to expose the source area S1 and the drain area D1. Each of the first insulating layer 10 and the second insulating layer 20 may be an inorganic layer.

Connection electrodes CNE1 and CNE2 may be disposed on the second insulating layer 20. A first connection electrode CNE1 may electrically connect the source area S1 of the first transistor T1 to the drain D3 of the third transistor T3 shown in FIG. 2. A second connection electrode CNE2 may electrically connect the drain area D1 of the first transistor T1 to the signal line for receiving the first voltage ELVDD shown in FIG. 2. The gate G1 of the first transistor T1 and the connection electrodes CNE1 and CNE2 may be disposed at (e.g., in or on) the same layer as each other. The gate G1 of the first transistor T1 may overlap with the channel area A1.

A third insulating layer 30 may be disposed on the second insulating layer 20. A third connection electrode CNE3 may be disposed on the third insulating layer 30. The third connection electrode CNE3 may be connected to the first connection electrode CNE1 via a contact hole CNT2 defined through (e.g., penetrating) the third insulating layer 30. A fourth insulating layer 40 may be disposed on the third insulating layer 30. An anode AE2 may be disposed on the fourth insulating layer 40. The anode AE2 may be connected to the third connection electrode CNE3 via a contact hole CNT3 defined through (e.g., penetrating) the fourth insulating layer 40. Each of the third insulating layer 30 and the fourth insulating layer 40 may be an organic layer. Anodes AE1 and AE3 of the first pixel area PXA-R and the third pixel area PXA-B may be disposed at (e.g., in or on) the same layer as the layer at (e.g., in or on) which the anode AE2 of the second pixel area PXA-G is disposed.

The light emitting element OLED and a pixel definition layer PDL may be disposed on the fourth insulating layer 40. The pixel definition layer PDL may be provided with an opening OP defined (e.g., penetrating) therethrough to expose at least a portion of the anode AE2. The openings OP of the pixel definition layer PDL may be defined in the light emitting areas EA1, EA2, and EA3 to correspond to the anodes AE1, AE2, and AE3 of the first pixel area PXA-R, the second pixel area PXA-G, and the third pixel area PXA-B, respectively. An area between the light emitting areas EA1, EA2, and EA3, i.e., an area in which the pixel definition layer PDL is disposed, may be defined as a non-light-emitting area NEA.

A hole control layer HCL may be commonly disposed over the light emitting areas EA1, EA2, and EA3 and the non-light-emitting area NEA. A common layer, such as the hole control layer HCL, may be disposed in the display area DA shown in FIG. 3A to overlap with a plurality of unit pixels PXU. The hole control layer HCL may include a hole transport layer and a hole injection layer.

A light emitting structure EML may be disposed on the hole control layer HCL. The light emitting structure EML may be commonly disposed over the light emitting areas EA1, EA2, and EA3 and the non-light-emitting area NEA. The light emitting structure EML may generate source light. The light emitting structure EML may include at least one light emitting layer.

An electron control layer ECL may be disposed on the light emitting structure EML. The electron control layer ECL may include an electron transport layer and an electron injection layer. The cathode CE may be disposed on the electron control layer ECL. The thin film encapsulation layer TFE may be disposed on the cathode CE. The thin film encapsulation layer TFE may be commonly disposed over a plurality of unit pixels PXU in the display area DA shown in FIG. 3A. In the present embodiment, the thin film encapsulation layer TFE may directly cover the cathode CE.

The thin film encapsulation layer TFE may include at least one inorganic layer or organic layer. The thin film encapsulation layer TFE may include a first inorganic encapsulation layer ITL1, an organic encapsulation layer OTL, and a second inorganic encapsulation layer ITL2, which are sequentially stacked. The organic encapsulation layer OTL may be disposed between the first inorganic encapsulation layer ITL1 and the second inorganic encapsulation layer ITL2. The first inorganic encapsulation layer ITL1 and the second inorganic encapsulation layer ITL2 may protect the light emitting element layer EDL from moisture and oxygen. The organic encapsulation layer OTL may protect the light emitting element layer EDL from a foreign substance, such as dust particles. The first inorganic encapsulation layer ITL1 and the second inorganic encapsulation layer ITL2 may include at least one of silicon nitride, silicon oxynitride, silicon oxide, titanium oxide, or aluminum oxide. The organic encapsulation layer OTL may include a polymer (e.g., an acrylic-based organic layer), but the present disclosure is not limited thereto or thereby.

FIG. 3B shows that the thin film encapsulation layer TFE includes two inorganic layers and one organic layer as a representative example, but the thin film encapsulation layer TFE is not necessarily limited thereto or thereby. For example, the thin film encapsulation layer TFE may include three inorganic layers and two organic layers, and in this case, the thin film encapsulation layer TFE may have a structure in which the inorganic layers and the organic layers are alternately stacked one on another. The display panel 100 may further include a refractive index control layer disposed above the thin film encapsulation layer TFE to increase a light emission efficiency.

In the present embodiment, the light emitting structure EML may generate a first color source light. In addition, according to an embodiment, the light emitting structure EML may generate the first color source light and a second color source light. According to an embodiment, the first color source light may be one of the blue light or the red light, and the second color source light may be another one of the green light, the blue light, or the red light.

The light emitting structure EML may include at least one light emitting layer. The light emitting layer may include a light emitting material for generating the first color source light. The light emitting layer may include the light emitting material for generating the first color source light, and a light emitting material for generating the second color source light. The light emitting structure EML may include the light emitting layer for generating the first color source light and the light emitting layer for generating the second color source light. The light emitting layer may include an organic light emitting material or an inorganic light emitting material. The light emitting structure EML may include a first light emitting layer, a charge generation layer, and a second light emitting layer, which are sequentially stacked in the third direction DR3. The first light emitting layer may generate one of the first color source light or the second color source light, and the second light emitting layer may generate the other of the first color source light or the second color source light.

The light conversion panel 200 will be described in more detail with reference to FIG. 3B. A synthetic resin material SRM may be disposed in the cell gap GP between the light conversion panel 200 and the display panel 100. As the light conversion panel 200 and the display panel 100 are connected (e.g., attached or coupled) with the synthetic resin material SRM interposed therebetween, the synthetic resin material SRM is located in the cell gap GP.

The light conversion panel 200 may include a second base layer BL2, color filters CF-R, CF-G, and CF-B, light control patterns CCF-R, CCF-G, and SP, a barrier wall BW, a plurality of insulating layers 200-1, 200-2, and 200-3, and a light shielding pattern LSP. The color filters CF-R, CF-G, and CF-B, the light control patterns CCF-R, CCF-G, and SP, the barrier wall BW, the insulating layers 200-1, 200-2, and 200-3, and the light shielding pattern LSP may be disposed on a lower surface of the second base layer BL2. The second base layer BL2 may include glass or a synthetic resin layer. The synthetic resin layer may include a heat curable resin. The synthetic resin layer may be a polyimide-based resin layer, but the present disclosure is not limited thereto or thereby.

The color filters CF-R, CF-G, and CF-B may include a first color filter CF-R, a second color filter CF-G, and a third color filter CF-B. The first color filter CF-R may be disposed to overlap with the first light emitting area EA1, the second color filter CF-G may be disposed to overlap with the second light emitting area EA2, and the third color filter CF-B may be disposed to overlap with the third light emitting area EA3. The first color filter CF-R and the second color filter CF-G may block the first color source light, and the third color filter CF-B may transmit the first color source light.

The first color filter CF-R, the second color filter CF-G, and the third color filter CF-B may define the first pixel area PXA-R, the second pixel area PXA-G, the third pixel area PXA-B, and the peripheral area NPXA. An area in which two or more color filters from among the first color filter CF-R, the second color filter CF-G, and the third color filter CF-B are disposed to overlap with each other may be defined as the peripheral area NPXA. A corresponding color filter (e.g., only one corresponding color filter) from among the first color filter CF-R, the second color filter CF-G, and the third color filter CF-B may be placed (e.g., may be located) in each of the first pixel area PXA-R, the second pixel area PXA-G, and the third pixel area PXA-B. As an example, the second pixel area PXA-G that does not overlap with the first color filter CF-R and the third color filter CF-B may be defined in (e.g., may overlap with) the second color filter CF-G. In a case where the display device DD further includes a black matrix pattern, the peripheral area NPXA may be defined as an area in which the black matrix pattern is located.

A first insulating layer 200-1 may be disposed under the first color filter CF-R, the second color filter CF-G, and the third color filter CF-B, and may cover the first color filter CF-R, the second color filter CF-G, and the third color filter CF-B. A second insulating layer 200-2 may cover the first insulating layer 200-1, and may provide a flat or substantially flat surface thereunder. The first insulating layer 200-1 may be an inorganic layer, and the second insulating layer 200-2 may be an organic layer.

The barrier wall BW may be disposed under the second insulating layer 200-2. When viewed in the plane (e.g., in a plan view), the barrier wall BW may overlap with the peripheral area NPXA. The barrier wall BW may be provided with openings BW-OP defined therethrough. The openings BW-OP may include a first opening BW-OPR, a second opening BW-OPG, and a third opening BW-OPB, which correspond to the first pixel area PXA-R, the second pixel area PXA-G, and the third pixel area PXA-B, respectively.

The first opening BW-OPR, the second opening BW-OPG, and the third opening BW-OPB may correspond to the first light emitting area EA1, the second light emitting area EA2, and the third light emitting area EA3, respectively. The expression “two components correspond to each other” may mean that the two components overlap with each other when viewed in a plane (e.g., in a plan view), but is not necessarily limited to having the same size as each other.

The barrier wall BW may include a synthetic resin. The barrier wall BW may include a suitable material having a transmittance equal to or smaller than a predetermined value. As an example, the barrier wall BW may include a light shielding material (e.g., a black coloring agent). The barrier wall BW may include a base resin, and a black dye or pigment mixed with the base resin. As an example, the barrier wall BW may include at least one of propylene glycol methyl ether acetate, 3-methoxy-n-butyl acetate, acrylate monomer, acrylic monomer, organic pigment, or acrylate ester.

The light control patterns CCF-R, CCF-G, and SP may include a first light control pattern CCF-R, a second light control pattern CCF-G, and a third light control pattern SP, which are respectively disposed in the openings BW-OP. Hereinafter, the first light control pattern CCF-R, the second light control pattern CCF-G, and the third light control pattern SP may be referred to as a first light conversion pattern CCF-R, a second light conversion pattern CCF-G, and a transparent resin pattern SP. The first light conversion pattern CCF-R, the second light conversion pattern CCF-G, and the transparent resin pattern SP may be arranged to correspond to the first pixel area PXA-R, the second pixel area PXA-G, and the third pixel area PXA-B, respectively.

The first light conversion pattern CCF-R may convert the first color source light to a third color light. The first color source light may be the blue light, and the third color light may be the red light. The third color light may be provided to the outside as a first output light after passing through the first color filter CF-R.

The second light conversion pattern CCF-G may convert the first source light to a second color light. The second color light may be the green light. The second color light may be provided to the outside as a second output light after passing through the second color filter CF-G.

The transparent resin pattern SP may transmit the first color source light without converting the first color source light to another color light. The first color source light may be provided to the outside as a third output light after passing through the third color filter CF-B.

The transparent resin pattern SP may include a transparent base resin. The transparent resin pattern SP may further include scattering particles mixed with the base resin. The scattering particles may scatter the first color source light passing through the transparent resin pattern SP to increase a viewing angle of the third pixel area PXA-B.

Each of the first light conversion pattern CCF-R, the second light conversion pattern CCF-G, and the transparent resin pattern SP may be formed through an inkjet process. Each of the first light conversion pattern CCF-R, the second light conversion pattern CCF-G, and the transparent resin pattern SP may be formed by providing a composition corresponding thereto to a space defined by the barrier wall BW (e.g., the openings BW-OP).

The first light conversion pattern CCF-R and the second light conversion pattern CCF-G may include a quantum dot. Each of the first light conversion pattern CCF-R and the second light conversion pattern CCF-G may include the base resin, the quantum dot, and the scattering particles. According to an embodiment, the scattering particles may be omitted as needed or desired.

The base resin may be a medium in which the quantum dots and/or the scattering particles are dispersed or mixed, and may include various suitable resin compositions that are generally referred to as a binder, but the present disclosure is not limited thereto or thereby. In the present disclosure, any suitable medium in which the quantum dots are dispersed or mixed may be referred to as the base resin, regardless of its name, additional functions, materials, and the like. The base resin may be a polymer resin. For example, the base resin may be an acrylic-based resin, a urethane-based resin, a silicone-based resin, or an epoxy-based resin. The base resin may be a transparent resin.

The scattering particles may include titanium oxide (TiO2) or silica-based nanoparticles. The scattering particles may scatter light incident thereto, and may increase an amount of the light provided to the outside of the display device DD. According to an embodiment, at least one of the first light conversion pattern CCF-R or the second light conversion pattern CCF-G may not include the scattering particles.

The quantum dots may be particles that change a wavelength of light incident thereto. The quantum dots may be a material having a crystal structure of several nanometers in size, contain hundreds to thousands of atoms, and exhibit a quantum confinement effect in which an energy band gap increases due to a small size. When light having a wavelength with an energy higher than that of the band gap is incident into the quantum dots, the quantum dots absorb the light and become excited, and then, the quantum dots emit light of a specific wavelength and fall to a ground state. The emitted light of the specific wavelength has an energy value corresponding to the band gap. The light-emitting property of the quantum dots due to the quantum confinement effect may be controlled by adjusting the size and the composition of the quantum dots.

A core of quantum dots may be selected from among a group II-VI compound, a group I-II-VI compound, a group II-IV-VI compound, a group I-II-IV-VI compound, a group III-VI compound, a group I-III-VI compound, a group III-V compound, a group III-II-V compound, a group II-IV-V compound, a group IV-VI compound, a group IV element, a group IV compound, and a suitable combination thereof.

The group II-VI compound may be selected from a binary compound selected from the group consisting of CdS, CdSe, CdTe, ZnS, ZnSe, ZnTe, ZnO, HgS, HgSe, HgTe, MgSe, MgS, and a suitable mixture thereof, a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a suitable mixture thereof, and/or a quaternary compound selected from the group consisting of CdZnSeS, CdZnSeTe, CdZnSTe, CdHgSeS, CdHgSeTe, CdHgSTe, HgZnSeS, HgZnSeTe, HgZnSTe, and a suitable mixture thereof. The group II-VI compound may further include a group I metal and/or a group IV element. The group I-II-VI compound may be selected from CuSnS or CuZnS, and the group II-IV-VI compound may be selected from ZnSnS. The group I-II-IV-VI compound may be selected from a quaternary compound selected from the group consisting of Cu2ZnSnS2, Cu2ZnSnS4, Cu2ZnSnSe4, Ag2ZnSnS2, and a suitable mixture thereof.

The group III-VI compound may include a binary compound, such as In2S3, In2Se3, and the like, a ternary compound, such as InGaS3, InGaSe3, and the like, or any suitable combination thereof.

The group I-III-VI compound may include a ternary compound selected from the group consisting of AgInS, AgInS2, CuInS, CuInS2, AgGaS2, CuGaS2 CuGaO2, AgGaO2, AgAlO2, and a suitable mixture thereof, or a quaternary compound of AgInGaS2, CuInGaS2, or the like.

The group III-V compound may be selected from a binary compound selected from the group consisting of GaN, GaP, GaAs, GaSb, AlN, AlP, AlAs, AlSb, InN, InP, InAs, InSb, and a suitable mixture thereof, a ternary compound selected from the group consisting of GaNP, GaNAs, GaNSb, GaPAs, GaPSb, AINP, AINAs, AINSb, AIPAs, AIPSb, InGaP, InAIP, InNP, InNAs, InNSb, InPAs, InPSb, and a suitable mixture thereof, and/or a quaternary compound selected from the group consisting of GaAINP, GaAINAs, GaAINSb, GaAIPAs, GaAIPSb, GaInNP, GaInNAs, GaInNSb, GaInPAs, GaInPSb, InAINP, InAINAs, InAINSb, InAIPAs, InAIPSb, and a suitable mixture thereof. The group III-V compound may further include a group II metal. For example, InZnP may be selected as a group III-II-V compound.

The group II-IV-V compound may include a ternary compound selected from the group consisting of ZnSnP, ZnSnP2, ZnSnAs2, ZnGeP2, ZnGeAs2, CdSnP2, CdGeP2, and a suitable mixture thereof.

The group IV-VI compound may be selected from a binary compound selected from the group consisting of SnS, SnSe, SnTe, PbS, PbSe, PbTe, and a suitable mixture thereof, a ternary compound selected from the group consisting of SnSeS, SnSeTe, SnSTe, PbSeS, PbSeTe, PbSTe, SnPbS, SnPbSe, SnPbTe, and a suitable mixture thereof, and/or a quaternary compound selected from the group consisting of SnPbSSe, SnPbSeTe, SnPbSTe, and a suitable mixture thereof. The group IV element may be selected from the group consisting of Si, Ge, and a suitable mixture thereof. The group IV compound may be a binary compound selected from the group consisting of SiC, SiGe, and a suitable mixture thereof.

In this case, the binary compound, the ternary compound, or the quaternary compound may exist in the particles at a uniform or substantially uniform concentration, or may exist in the same particle after being divided into a plurality of portions having different concentrations from one another. In addition, the quantum dots may have a core/shell structure in which one quantum dot surrounds (e.g., around a periphery of) another quantum dot. In the core/shell structure, the concentration of elements existing in the shell may have a concentration gradient that is lowered as a distance from the core decreases.

In some embodiments, the quantum dot may have a core-shell structure that includes a core including the above-described nanocrystal, and a shell surrounding (e.g., around a periphery of) the core. The shell of the quantum dot may serve as a protective layer to prevent or substantially prevent chemical modification of the core, and to maintain or substantially maintain semiconductor properties, and/or may serve as a charging layer to impart electrophoretic properties to the quantum dot. The shell may have a single-layer or multi-layered structure. The shell of the quantum dots may include metal oxides, non-metal oxides, semiconductor compounds, or suitable combinations thereof as representative examples.

The metal oxides or non-metal oxides may include a binary compound, such as SiO2, Al₂O₃, TiO2, ZnO, MnO, Mn2O3, Mn3O4, CuO, FeO, Fe2O3, Fe3O4, CoO, Co3O4, and/or NiO, or a ternary compound, such as MgAl2O4, CoFe2O4, NiFe2O4, and/or CoMn2O4, but the present disclosure is not necessarily limited thereto or thereby.

In addition, the semiconductor compounds may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, or AlSb, but the present disclosure is not necessarily limited thereto or thereby.

The quantum dots may have a full width of half maximum (FWHM) of a light emission wavelength spectrum of about 45 nm or less, for example, such as about 40 nm or less, or about 30 nm or less. The color purity and the color reproducibility may be improved within this range. In addition, because the light emitted through the quantum dots may be emitted in various directions (e.g., in all directions), an optical viewing angle may be improved.

The shape of the quantum dots may have a suitable shape commonly used in the art, but is not particularly limited. In more detail, spherical, pyramidal, multi-arm, or cubic nanoparticles, nanotubes, nanowires, nanofibers, nanoplatelets, or the like may be applied to the quantum dots.

The quantum dots may control the color of the emitted light depending on a particle size thereof, and accordingly, the quantum dots may have various suitable emission colors, such as blue, red, and green colors.

The third insulating layer 200-3 may cover the barrier wall BW, the first light conversion pattern CCF-R, the second light conversion pattern CCF-G, and the transparent resin pattern SP. As an example, the third insulating layer 200-3 may be an inorganic layer. According to an embodiment, the third insulating layer 200-3 may be omitted as needed or desired.

The light shielding pattern LSP may be disposed under the third insulating layer 200-3. The light shielding pattern LSP may include a light absorbing material (e.g., a black coloring agent). The light shielding pattern LSP may include a base resin and a black pigment, and/or a black dye mixed with the base resin.

The light shielding pattern LSP may have a higher composition ratio of the black coloring agent than that of the above-described barrier wall BW. Because the barrier wall BW has a relatively thinner thickness compared with the light shielding pattern LSP, the light shielding pattern LSP may be easily cured even though the light shielding pattern LSP has the high composition ratio of the black coloring agent.

The light shielding pattern LSP may be disposed between the display panel 100 and the barrier wall BW, and may overlap with a corresponding opening from among the openings BW-OP. The light shielding pattern LSP may overlap with a portion of the light control pattern disposed in the corresponding opening. An area where the light shielding pattern LSP overlaps with the corresponding opening may be the same or substantially the same as an area where the light shielding pattern LSP overlaps with the light control pattern. As shown in FIG. 3B, the light shielding pattern LSP may overlap with a portion of the second opening BW-OPG, and may overlap with a portion of the second light conversion pattern CCF-G.

The light shielding pattern LSP may shield an incident of a leak light LKL. The leak light LKL indicates a source light generated by the light emitting element disposed in the light emitting areas EA1, EA2, and EA3 and incident into the light control pattern or the pixel area adjacent to the light emitting areas EA1, EA2, and EA3, without being incident into the corresponding light control pattern or the corresponding pixel area. The leak light LKL may increase a light conversion efficiency of the light conversion patterns CCF-R and CCF-G, or may increase an amount of the light incident into the transparent resin pattern SP. Due to the leak light LKL, the pixel area may display a grayscale (e.g., a grayscale value or level) higher than a target grayscale (e.g., a target grayscale value or level). Consequently, the leak light LKL may cause a deterioration in the display quality of the display device DD.

According to the present embodiment, the light shielding pattern LSP may shield the leak light LKL from the first light emitting area EA1 and the third light emitting area EA3 from entering the second light conversion pattern CCF-G. In a case where the barrier wall BW including the light absorbing material has a width sufficient to shield the leak light, the leak light may be shielded without employing the light shielding pattern LSP. However, when the width (e.g., in the first direction DR1) of the barrier wall BW increases, the size of the first opening BW-OPR, the second opening BW-OPG, and the third opening BW-OPB decreases. When the size of the first opening BW-OPR, the second opening BW-OPG, and the third opening BW-OPB decreases, a probability of incorrectly providing the liquid resin composition may increase in the inkjet process to form the light control patterns CCF-R, CCF-G, and SP. As a resolution of the display device DD increases, the above-described probability of incorrectly providing the liquid resin composition increases.

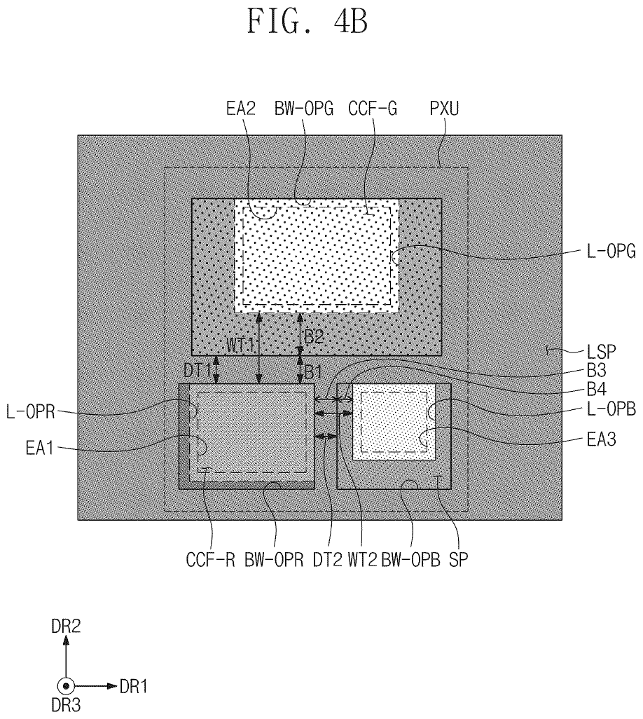

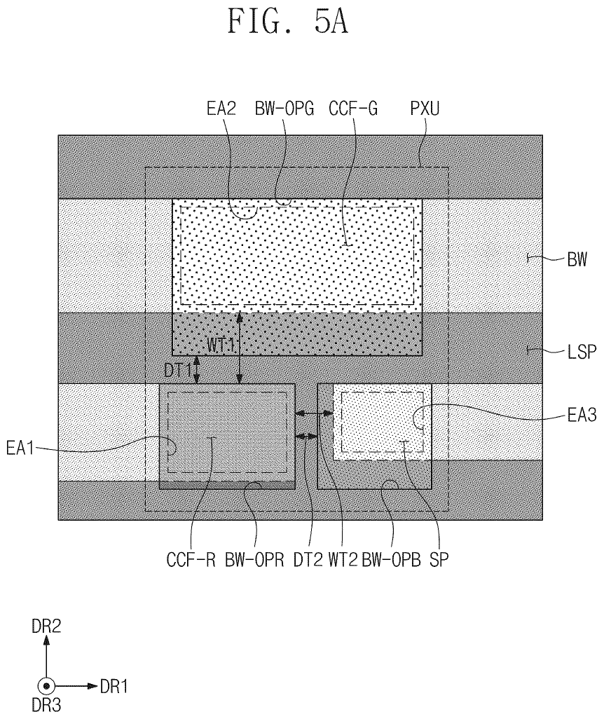

In the following description, the display device DD may shield the leak light LKL while securing the reliability of the inkjet process. Hereinafter, the shielding of the leak light will be described in more detail with reference to FIGS. 4A and 4B.

FIG. 4A is a plan view of the barrier wall BW and the light control patterns CCF-R, CCF-G, and SP according to an embodiment of the present disclosure. FIG. 4B is a plan view of the light shielding pattern LSP according to an embodiment of the present disclosure. Hereinafter, redundant description of the components that are the same or substantially the same as those described above with reference to FIG. 3B may not be repeated.

FIG. 4A shows positions of the first light emitting area EA1, the second light emitting area EA2, and the third light emitting area EA3 with respect to the first opening BW-OPR, the second opening BW-OPG, and the third opening BW-OPB. Each of the first light emitting area EA1, the second light emitting area EA2, and the third light emitting area EA3 may not be aligned with a corresponding opening from among the first opening BW-OPR, the second opening BW-OPG, and the third opening BW-OPB. The expression “the light emitting area is not aligned with the opening” may mean that a center of the light emitting area does not coincide with a center of the opening. In addition, the expression “the light emitting area is not aligned with the opening” may mean that distances between an edge of the light emitting area and an edge of the opening at both sides in the first direction DR1 or the second direction DR2 are different.

Referring to the second light emitting area EA2 and the second opening BW-OPG, the second light emitting area EA2 may be disposed to be biased upward (e.g., in the second direction DR2) with respect to the second opening BW-OPG. The second light emitting area EA2 may be disposed to be biased upward with respect to the second opening BW-OPG to secure a separation distance from the first light emitting area EA1 and the third light emitting area EA3. In other words, the second opening BW-OPG may be expanded to both sides in the first direction DR1 to secure a relatively larger size compared with that of the second light emitting area EA2. In addition, the second opening BW-OPG may be expanded more to a downward side than to an upward side in the second direction DR2 to secure a relatively larger size compared with that of the second light emitting area EA2.

The first opening BW-OPR may be expanded more to a left side than to a right side in the first direction DR1 to secure a relatively larger size compared with that of the first light emitting area EA1. In addition, the first opening BW-OPR may be expanded more to the downward side than to the upward side in the second direction DR2 to secure a relatively larger size compared with that of the first light emitting area EA1. The third opening BW-OPB may be expanded to both sides in the first direction DR1 to secure a relatively larger size compared with that of the third light emitting area EA3, and may be expanded more to the downward side than to the upward side in the second direction DR2.

The second opening BW-OPG may be disposed to be spaced apart from the first opening BW-OPR and the third opening BW-OPB in the second direction DR2. The second opening BW-OPG may be disposed to be spaced apart from the first opening BW-OPR and the third opening BW-OPB by a first distance DT1 in the second direction DR2. The first distance DT1 may be a width of the barrier wall BW of FIG. 3B, and the first distance DT1 may be measured at (e.g., in or on) a lower surface of the barrier wall BW.

The first distance DT1 may be the shortest distance from the second opening BW-OPG to each of the first opening BW-OPR and the third opening BW-OPB. The first distance DT1 may be within a range from about 5 μm to about 8 μm. The first distance DT1 having the above range may mean that the width of the barrier wall BW disposed between the first opening BW-OPR and the second opening BW-OPG is small, and the width of the barrier wall BW disposed between the first opening BW-OPR and the third opening BW-OPB is small.

The first opening BW-OPR may be disposed to be spaced apart from the third opening BW-OPB by a second distance DT2 in the first direction DR1. The second distance DT2 may be measured under the same condition as that of the first distance DT1. The second distance DT2 may be within a range from about 5 μm to about 8 μm.

As the width of the barrier wall BW disposed between the first opening BW-OPR, the second opening BW-OPG, and the third opening BW-OPB is reduced, the first opening BW-OPR, the second opening BW-OPG, and the third opening BW-OPB of the relatively larger size may be secured. Each of the first opening BW-OPR, the second opening BW-OPG, and the third opening BW-OPB may have a width equal to or greater than about 41 μm in each of the first direction DR1 and the second direction DR2. In an embodiment, the above-described numerical width may be secured in order for an inkjet head to accurately supply an ink composition to each of the first opening BW-OPR, the second opening BW-OPG, and the third opening BW-OPB.

Referring to FIG. 4B, the light shielding pattern LSP may entirely overlap with the barrier wall BW. The light shielding pattern LSP may include a first-first opening L-OPR, a second-first opening L-OPG, and a third-first opening L-OPB, which correspond to the first opening BW-OPR, the second opening BW-OPG, and the third opening BW-OPB, respectively. Each of the first-first opening L-OPR, the second-first opening L-OPG, and the third-first opening L-OPB may have a size smaller than that of a corresponding opening from among the first opening BW-OPR, the second opening BW-OPG, and the third opening BW-OPB. In addition, each of the first-first opening L-OPR, the second-first opening L-OPG, and the third-first opening L-OPB may be defined inside (e.g., within) the corresponding opening from among the first opening BW-OPR, the second opening BW-OPG, and the third opening BW-OPB. In other words, in a plan view, the corresponding opening from among the first opening BW-OPR, the second opening BW-OPG, and the third opening BW-OPB may surround (e.g., around a periphery of) the corresponding one from among the first-first opening L-OPR, the second-first opening L-OPG, and the third-first opening L-OPB.

Each of the first-first opening L-OPR, the second-first opening L-OPG, and the third-first opening L-OPB may be aligned with a corresponding light emitting area from among the first light emitting area EA1, the second light emitting area EA2, and the third light emitting area EA3. The expression “the opening is aligned with the light emitting area” may mean that a center of the opening coincides with a center of the light emitting area. In addition, the expression “the opening is aligned with the light emitting area” may mean that distances between an edge of the opening and an edge of the light emitting area at both side in the first direction DR1 are the same as each other, and distances between an edge of the opening and an edge of the light emitting area at both sides in the second direction DR2 are the same as each other.

The first pixel area PXA-R, the second pixel area PXA-G, and the third pixel area PXA-B described above with reference to FIG. 3B may be the same or substantially the same as the first-first opening L-OPR, the second-first opening L-OPG, and the third-first opening L-OPB of FIG. 4B. The edge of each of the first pixel area PXA-R, the second pixel area PXA-G, and the third pixel area PXA-B may overlap with or may be aligned with the edge of the corresponding opening from among the first-first opening L-OPR, the second-first opening L-OPG, and the third-first opening L-OPB. Accordingly, the width of each of the first pixel area PXA-R, the second pixel area PXA-G, and the third pixel area PXA-B may be the same or substantially the same as the width of the corresponding opening from among the first-first opening L-OPR, the second-first opening L-OPG, and the third-first opening L-OPB.

The light shielding pattern LSP may partially overlap with each of the first opening BW-OPR, the second opening BW-OPG, and the third opening BW-OPB, but the present disclosure is not limited thereto or thereby. According to an embodiment, the light shielding pattern LSP may partially overlap with at least one opening from among the first opening BW-OPR, the second opening BW-OPG, or the third opening BW-OPB.

According to the present embodiment, the light shielding pattern LSP may partially overlap with each of the first light conversion pattern CCF-R, the second light conversion pattern CCF-G, and the transparent resin pattern SP. The light shielding pattern LSP may overlap with a left side portion of the first light conversion pattern CCF-R in the first direction DR1, and may overlap with a lower portion of the first light conversion pattern CCF-R in the second direction DR2. The light shielding pattern LSP may overlap with portions of both sides of each of the second light conversion pattern CCF-G and the transparent resin pattern SP in the first direction DR1, and may overlap with a lower portion of each of the second light conversion pattern CCF-G and the transparent resin pattern SP in the second direction DR2.

In the area where the first distance DT1 is measured, a first portion B1 (e.g., a first area) of the light shielding pattern LSP may overlap with the barrier wall BW. A second portion B2 (e.g., a second area) of the light shielding pattern LSP may extend from the first portion B1 of the light shielding pattern LSP, and may overlap with the second light conversion pattern CCF-G. A sum WT1 of the width of the first portion B1 of the light shielding pattern LSP and the width of the second portion B2 of the light shielding pattern LSP in the second direction DR2 may be greater than the first distance DT1. In the area where the second distance DT2 is measured, a third portion B3 of the light shielding pattern LSP may overlap with the barrier wall BW. A fourth portion B4 of the light shielding pattern LSP may extend from the third portion B3 of the light shielding pattern LSP, and may overlap with the transparent resin pattern SP. A sum WT2 of the width of the third portion B3 of the light shielding pattern LSP and the width of the fourth portion B4 of the light shielding pattern LSP in the first direction DR1 may be greater than the second distance DT2.

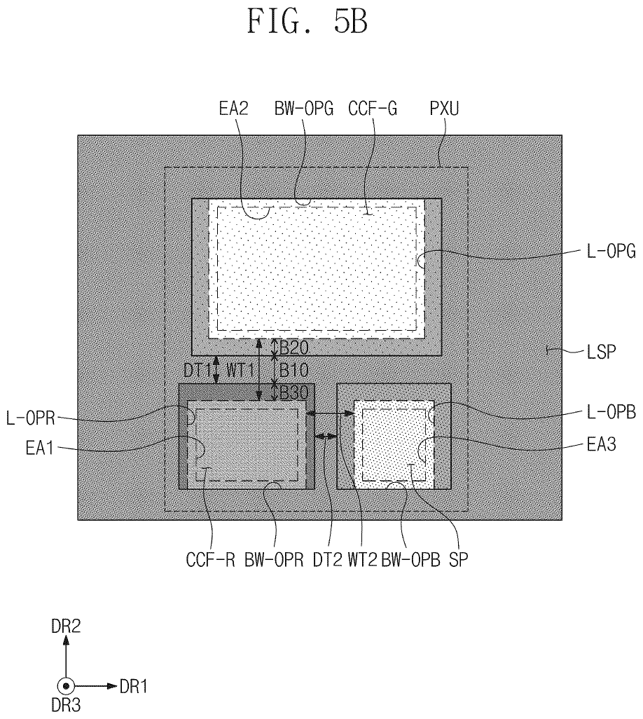

FIGS. 5A and 5B are plan views of a light shielding pattern LSP according to one or more embodiments of the present disclosure. Hereinafter, redundant description of the components that are the same or substantially the same as those described above with reference to FIGS. 3A to 4B may not be repeated.

Referring to FIG. 5A, unlike the light shielding pattern LSP of FIG. 4B, the light shielding pattern LSP of FIG. 5A may expose a portion of a barrier wall BW when viewed in the plane (e.g., in a plan view). As described above with reference to FIG. 3B, because the light shielding pattern LSP is disposed to shield the leak light LKL, it may be sufficient for the light shielding pattern LSP to overlap with areas between the first light emitting area EA1, the second light emitting area EA2, and the third light emitting area EA3. In a case where a distance between the unit pixels PXU that are adjacent to each other is relatively large, the light shielding pattern LSP may expose a portion of the barrier wall BW disposed between the unit pixels PXU.

Referring to FIG. 5B, the light shielding pattern LSP may overlap with portions of both sides of each of the first light conversion pattern CCF-R and the transparent resin pattern SP in the first direction DR1, and may overlap with an upper portion of each of the first light conversion pattern CCF-R and the transparent resin pattern SP in the second direction DR2. An area in which the light shielding pattern LSP overlaps with the second light conversion pattern CCF-G may be smaller than that of the light shielding pattern LSP of FIG. 4B. Accordingly, a second-first opening L-OPG may increase, and a light emitting area corresponding to the second light emitting area EA2 may increase.

The light shielding pattern LSP may overlap with the barrier wall BW, a first-first opening L-OPR, the second-first opening L-OPG, and a third-first opening L-OPB. In an area where a first distance DT1 is measured, a first portion B10 of the light shielding pattern LSP may overlap with the barrier wall BW. A second portion B20 of the light shielding pattern LSP may extend from the first portion B10 of the light shielding pattern LSP, and may overlap with the second light conversion pattern CCF-G. A third portion B30 of the light shielding pattern LSP may extend from the first portion B10 of the light shielding pattern LSP, and may overlap with the first light conversion pattern CCF-R. A sum WT1 of the width of each of the first portion B10, the second portion B20, and the third portion B30 of the light shielding pattern LSP in the second direction DR2 may be greater than the first distance DT1. The sum WT1 of the width of each of the first portion B1 and the second portion B2 of the light shielding pattern LSP described above with reference to FIG. 4B may be the same or substantially the same as the sum WT1 of the width of each of the first portion B10, the second portion B20, and the third portion B30 of the light shielding pattern LSP described with reference to FIG. 5B. According to the present embodiment, the light emitting area corresponding to the second light emitting area EA2 may increase, and an interference of the leak light LKL may be reduced.

A portion of the light shielding pattern LSP, which is disposed between the first-first opening L-OPR and the third-first opening L-OPB, may shield the leak light LKL in the first light emitting area EA1 and the third light emitting area EA3 for the same or substantially the same reasons as those described above with reference to the first portion B10 to the third portion B30 disposed between the first-first opening L-OPR and the second-first opening L-OPG of the light shielding pattern LSP.

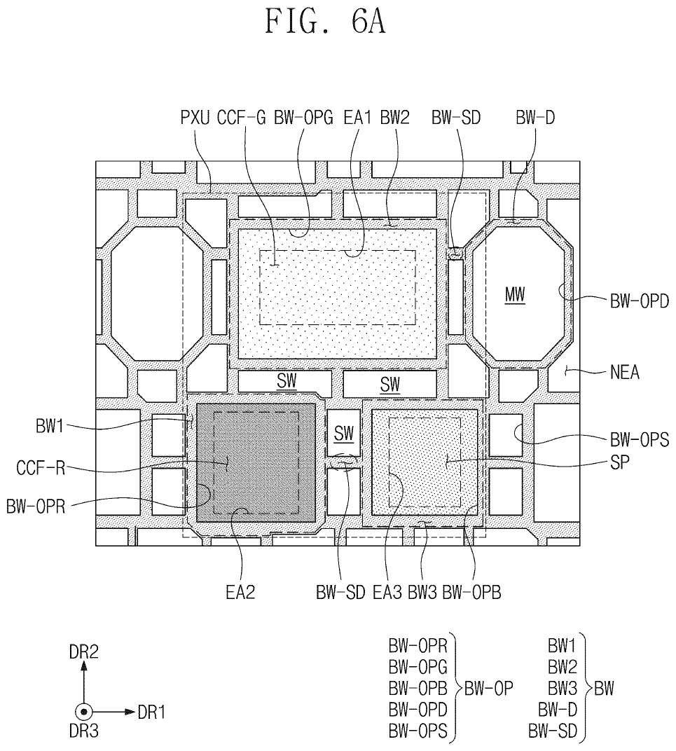

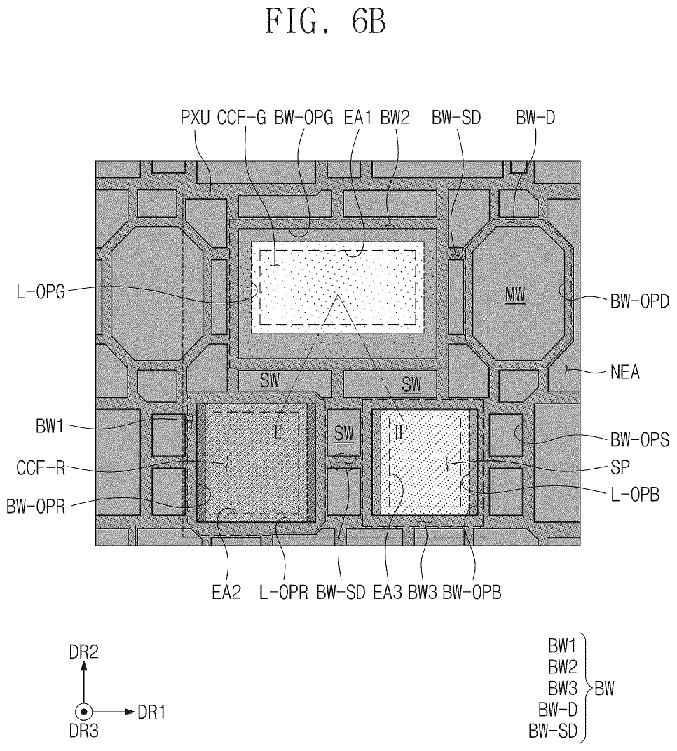

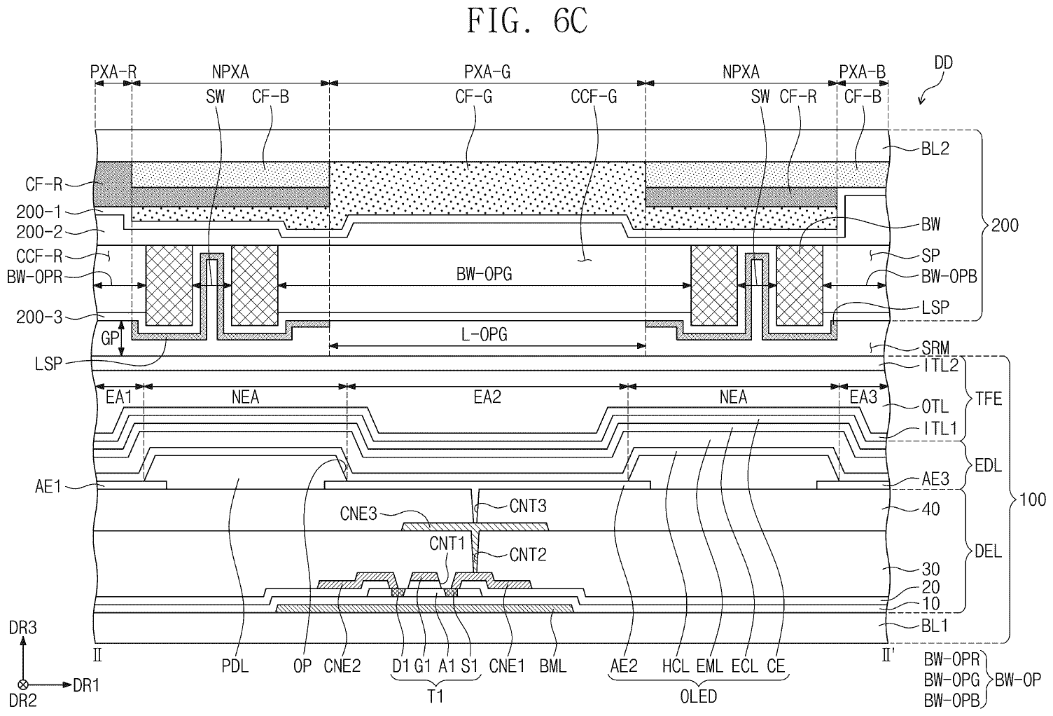

FIG. 6A is a plan view of the barrier wall BW and the light control patterns CCF-R, CCF-G, and SP according to an embodiment of the present disclosure. FIG. 6B is a plan view of the light shielding pattern LSP according to an embodiment of the present disclosure. FIG. 6C is a cross-sectional view of the light conversion panel 200 taken along the line II-II′ of FIG. 6B. Hereinafter, redundant description of the same or substantially the same components as those described above with reference to FIGS. 3A to 5B may not be repeated.

Referring to FIG. 6A, a dummy opening BW-OPD and a sub-opening BW-OPS may be further defined through the barrier wall BW. Each of the dummy opening BW-OPD and the sub-opening BW-OPS may be provided in a plurality.

The barrier wall BW may include a first barrier wall BW1 that defines the first opening BW-OPR corresponding to the first light emitting area EA1, a second barrier wall BW2 that defines the second opening BW-OPG corresponding to the second light emitting area EA2, and a third barrier wall BW3 that defines the third opening BW-OPB corresponding to the third light emitting area EA3. The first barrier wall BW1, the second barrier wall BW2, and the third barrier wall BW3 may be disposed to be spaced apart from each other.

The barrier wall BW may further include a main dummy barrier wall BW-D overlapping with the non-light-emitting area NEA, and defining the dummy opening BW-OPD. The main dummy barrier wall BW-D may be disposed at both sides of the second barrier wall BW2 in the first direction DR1. The main dummy barrier wall BW-D may overlap with the unit pixel that is adjacent to the unit pixel PXU shown in FIG. 6A.

The main dummy barrier wall BW-D may define a main well area MW. The main well area MW may accommodate the liquid resin composition that is inaccurately provided during the inkjet process performed to form the light control patterns CCF-R, CCF-G, and SP described above with reference to FIG. 3B. For example, the main well area MW may accommodate the liquid resin composition that is not accurately provided in the second opening BW-OPG. In a case where the main well area MW is not formed in the main dummy barrier wall BW-D, the main dummy barrier wall BW-D may be arranged as an insulating pattern that occupies a certain area. The resin composition that is inaccurately provided on the insulating pattern may form a protrusion, and the protrusion may cause defects in the manufacturing process of the display device. The main well area MW may prevent or substantially prevent the defects from occurring.

The barrier wall BW may further include a sub-dummy barrier wall BW-SD overlapping with the non-light-emitting area NEA. The sub-dummy barrier wall BW-SD may connect the barrier walls that are adjacent to each other from among the first barrier wall BW1, the second barrier wall BW2, the third barrier wall BW3, and the main dummy barrier wall BW-D to each other. The sub-dummy barrier wall BW-SD may connect the first barrier wall BW1, the second barrier wall BW2, the third barrier wall BW3, and the main dummy barrier wall BW-D to each other into one structure, and thus, may improve a durability of the barrier wall structure. The barrier walls that are adjacent to each other from among the first barrier wall BW1, the second barrier wall BW2, the third barrier wall BW3, and the main dummy barrier wall BW-D and two of the sub-dummy barrier walls BW-SD may define the sub-opening BW-OPS. The sub-opening BW-OPS may correspond to a sub-well area SW. The sub-well area SW may also accommodate the liquid resin composition that is inaccurately provided in the manufacturing process, which will be described in more detail below.

Referring to FIGS. 6B and 6C, the first-first opening L-OPR, the second-first opening L-OPG, and the third-first opening L-OPB may be defined through (e.g., may penetrate) the light shielding pattern LSP. The light shielding pattern LSP may overlap with the first barrier wall BW1, the second barrier wall BW2, the third barrier wall BW3, the main dummy barrier wall BW-D, and the sub-dummy barrier wall BW-SD.

The light shielding pattern LSP may overlap with the main well area MW and the sub-well area SW. FIG. 6C shows a structure in which the light shielding pattern LSP is disposed in the sub-well area SW.

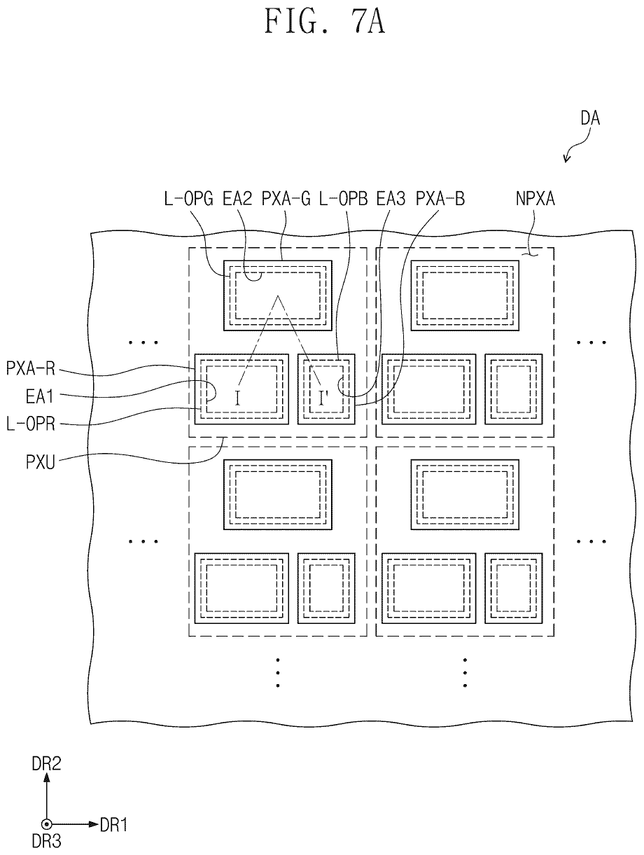

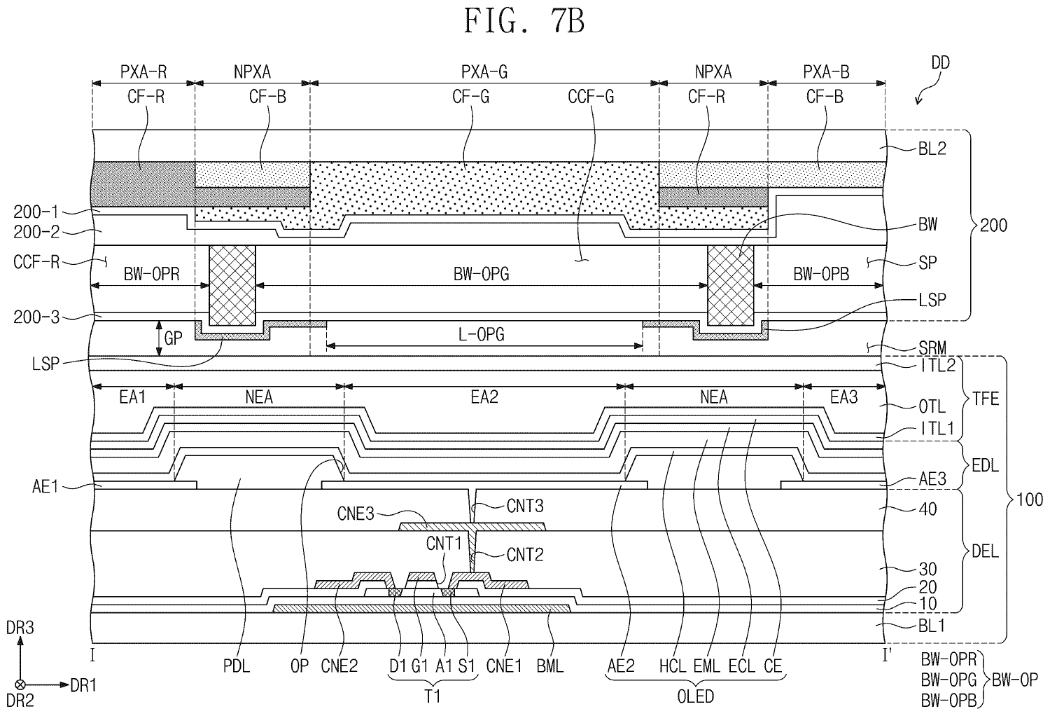

FIG. 7A is an enlarged plan view of the display area DA according to an embodiment of the present disclosure. FIG. 7B is a cross-sectional view of the display device DD taken along the line I-I′ of FIG. 7A. Hereinafter, redundant description of the same or substantially the same components as those described above with reference to FIGS. 3A and 3B may not be repeated.

Referring to FIGS. 7A and 7B, each of the first pixel area PXA-R, the second pixel area PXA-G, and the third pixel area PXA-B may have a size greater than that of the corresponding opening from among the first-first opening L-OPR, the second-first opening L-OPG, and the third-first opening L-OPB. Each of the first-first opening L-OPR, the second-first opening L-OPG, and the third-first opening L-OPB may be disposed in the corresponding pixel area from among the first pixel area PXA-R, the second pixel area PXA-G, and the third pixel area PXA-B. Accordingly, a width of each of the first pixel area PXA-R, the second pixel area PXA-G, and the third pixel area PXA-B may be greater than a width of the corresponding opening from among the first-first opening L-OPR, the second-first opening L-OPG, and the third-first opening L-OPB.

As the first pixel area PXA-R, the second pixel area PXA-G, and the third pixel area PXA-B may have the size greater than the areas defined by the first-first opening L-OPR, the second-first opening L-OPG, and the third-first opening L-OPB, an aperture ratio of the display device DD may increase.

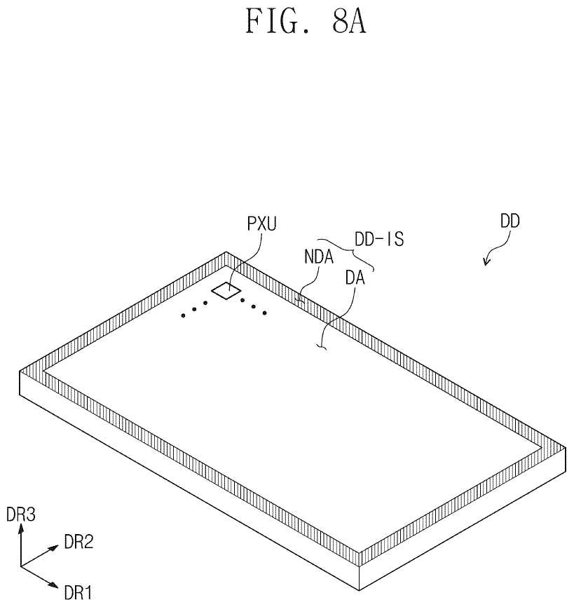

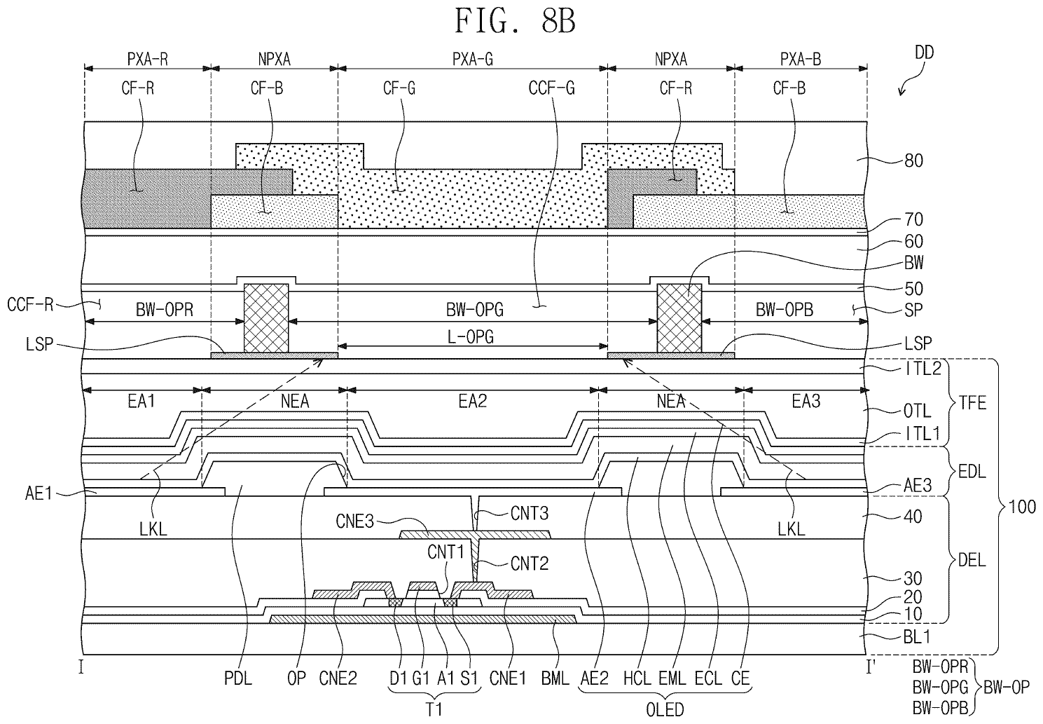

FIG. 8A is a perspective view of a display device DD according to an embodiment of the present disclosure. FIG. 8B is a cross-sectional view of the display device DD according to an embodiment of the present disclosure. Hereinafter, redundant description of the same or substantially the same components as those described above with reference to FIGS. 3A and 7B may not be repeated.

Unlike the display device DD described above with reference to FIGS. 1A to 7B, the display device DD according to the present embodiment may include one base layer BL1. In the manufacturing process, a coupling process of a display panel 100 and a light conversion panel 200 may be omitted, and the components thereof may be sequentially formed on the base layer BL1.

Referring to FIGS. 8A and 8B, the display panel 100 included in the display device DD is the same or substantially the same as the display panel 100 described above with reference to FIG. 3B. A light shielding pattern LSP may be disposed on the thin film encapsulation layer TFE. A barrier wall BW may be disposed on the light shielding pattern LSP. A first light conversion pattern CCF-R, a second light conversion pattern CCF-G, and a transparent resin pattern SP may be disposed in openings BW-OP of the barrier wall BW, respectively. A fifth insulating layer 50 may cover the barrier wall BW, the first light conversion pattern CCF-R, the second light conversion pattern CCF-G, and the transparent resin pattern SP. As an example, the fifth insulating layer 50 may be an inorganic layer.

A sixth insulating layer 60 may be disposed on the fifth insulating layer 50. The sixth insulating layer 60 may have a refractive index lower than that of the fifth insulating layer 50. The refractive index of the sixth insulating layer 60 may be equal to or greater than about 1.1, and equal to or smaller than about 1.5. The refractive index of the sixth insulating layer 60 may be determined depending on a ratio of hollow particles and/or voids distributed in the sixth insulating layer 60. The source light and the converted light may be provided more vertically due to the sixth insulating layer 60.

A seventh insulating layer 70 may be disposed on the sixth insulating layer 60. The seventh insulating layer 70 may be an inorganic layer that encapsulates a structure disposed thereunder. The seventh insulating layer 70 may be omitted as needed or desired.

A first color filter CF-R, a second color filter CF-G, and a third color filter CF-B may be disposed on the seventh insulating layer 70. An eighth insulating layer 80 may be disposed on the first color filter CF-R, the second color filter CF-G, and the third color filter CF-B, and the eighth insulating layer 80 may cover the first color filter CF-R, the second color filter CF-G, and the third color filter CF-B to provide a flat or substantially flat surface. The eighth insulating layer 80 may be an organic layer.

In some embodiments, the barrier wall BW may have the same or substantially the same shape and arrangement as those of any one of the barrier walls BW described above with reference to FIGS. 4A to 7B.

Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a display panel comprising a first light emitting area configured to emit a source light;
a barrier wall on the display panel, and having a first opening corresponding to the first light emitting area;
a first light control pattern in the first opening; and
a light shielding pattern between the display panel and the barrier wall, and overlapping with the barrier wall and the first opening,
wherein the light shielding pattern overlaps with a portion of the first light control pattern.

2. The display device of claim 1, wherein the first light emitting area is located in the first opening in a plan view, and the first light emitting area is biased to one side of the first opening in a first direction.

3. The display device of claim 1, wherein the light shielding pattern has a first-first opening corresponding to the first opening, and the first-first opening has a size smaller than a size of the first opening in a plan view.

4. The display device of claim 3, wherein the light shielding pattern entirely overlaps with the barrier wall in a plan view.

5. The display device of claim 1, further comprising a first color filter on the barrier wall,
wherein the first light control pattern is configured to convert the source light to a first output light having a color different from a color of the source light, and
wherein the first color filter is configured to block the source light and transmit the first output light.

6. The display device of claim 5, wherein the first light control pattern comprises a base resin, and a quantum dot dispersed in the base resin.

7. The display device of claim 5, further comprising a second color filter and a third color filter overlapping with the first color filter,
wherein the first color filter comprises a first pixel area that does not overlap with the second color filter and the third color filter, and
wherein the first pixel area overlaps with the first light emitting area in a plan view.

8. The display device of claim 7, wherein the light shielding pattern has a first-first opening corresponding to the first opening,
wherein the first-first opening is smaller than the first opening in a plan view, and
wherein the first pixel area has a width equal to or greater than a width of the first-first opening in a first direction.

9. The display device of claim 1, further comprising a second light control pattern,
wherein the display panel further comprises a second light emitting area configured to emit the source light,
wherein the barrier wall has a second opening corresponding to the second light emitting area, and
wherein the second light control pattern is in the second opening.

10. The display device of claim 9, wherein the light shielding pattern further overlaps with the second opening.

11. The display device of claim 10, wherein:
the first opening and the second opening are spaced from each other in a first direction;
a first portion of the light shielding pattern overlaps with an area between the first opening and the second opening in the first direction;
a second portion of the light shielding pattern extends from the first portion of the light shielding pattern, and overlaps with the first opening; and
a third portion of the light shielding pattern extends from the first portion of the light shielding pattern, and overlaps with the second opening.

12. The display device of claim 9, wherein a shortest distance in a first direction between the first opening and the second opening is within a range from about 5 micrometers to about 8 micrometers.

13. The display device of claim 12, wherein:
a first portion of the light shielding pattern overlaps with an area between the first opening and the second opening;
a second portion of the light shielding pattern extends from the first portion of the light shielding pattern, and overlaps with the first opening; and
a sum of a width of the first portion and a width of the second portion of the light shielding pattern in the first direction is greater than the shortest distance.

14. The display device of claim 12, wherein the first opening has a width equal to or greater than about 41 micrometers in the first direction.

15. The display device of claim 1, further comprising a base layer facing the display panel in a thickness direction of the display panel,
wherein the barrier wall is on a lower surface of the base layer.

16. The display device of claim 1, wherein the barrier wall further has a dummy opening defining a main well area that does not overlap with the first light emitting area in a plan view, and a sub-opening defining a sub-well area between the first light emitting area and the main well area, and
wherein the light shielding pattern overlaps with the main well area or the sub-well area.

17. A display device comprising:
a display panel comprising a light emitting element; and
a light conversion panel spaced from the display panel in a thickness direction of the display panel, the light conversion panel comprising:
a base layer;
a barrier wall on a lower surface of the base layer, and having an opening corresponding to the light emitting element;
a light control pattern in the opening; and
a light shielding pattern under the barrier wall, and overlapping with the barrier wall and the opening,
wherein the light shielding pattern overlaps with a portion of the light control pattern.

18. The display device of claim 17, wherein the light emitting element is in the opening in a plan view, and the light emitting element is biased to one side of the opening in a first direction.

19. A display device comprising:
a light emitting element;
a thin film encapsulation layer encapsulating the light emitting element;
a barrier wall on the thin film encapsulation layer, and having an opening corresponding to the light emitting element;
a light control pattern in the opening; and
a light shielding pattern between the barrier wall and the thin film encapsulation layer, and overlapping with the barrier wall and the opening,
wherein the light shielding pattern overlaps with a portion of the light control pattern.

20. The display device of claim 19, wherein the light emitting element is in the opening in a plan view, and the light emitting element is biased to one side of the opening in a first direction.
